(19) United States
(12) Patent Application Publication
(10) Pub. No.: US 2026/0097473 A1
(43) Pub. Date: Apr. 9, 2026

(54) OPERATING PARAMETER DISPLAY FOR POWER TOOL

(71) Applicant: MILWAUKEE ELECTRIC TOOL CORPORATION, Brookfield, WI (US)

(72) Inventors: Mitchell A. Gibson, New Berlin, WI (US); Scott R. Fischer, Menomonee Falls, WI (US)

(21) Appl. No.: 19/352,154

(22) Filed: Oct. 7, 2025

Related U.S. Application Data
(60) Provisional application No. 63/704,353, filed on Oct. 7, 2024.

(51) Int. Cl. B25B 23/147; B25F 5/00; B25F 5/02; H05K 5/00

(52) U.S. Cl. CPC B25B 23/147; B25F 5/001; B25F 5/006; B25F 5/028; H05K 5/0018; H05K 5/0086

(57) ABSTRACT

A power tool includes a housing with first and second clamshell portions. A motor positioned within the housing is configured to rotate a motor shaft. A gear case coupled to the housing encloses a drive train to transmit torque from the motor shaft to an output drive extending from a front end of the gear case. A reaction arm coupled to the gear case limits rotation of the gear case. The power tool includes an interface assembly with an interface housing having a top portion positioned within the housing between the clamshell portions and a bottom portion extending outside the housing. The top portion includes a lens opening, and the bottom portion includes actuator openings. An interface circuit board coupled includes a display panel in line with the lens opening and switches positioned in line with the actuator openings. A lens is positioned within the lens opening.

### CROSS-REFERENCE TO RELATED APPLICATIONS

This application claims priority to U.S. Provisional Patent Application No. 63/704,353, filed October 7, 2024, the entire content of which is incorporated herein by reference.

### FIELD

The present disclosure relates to power tools, and more specifically a display assembly for displaying one or more operating parameters of a power tool.

### BACKGROUND

Reaction arm tools are a form of rotary power tool used to drive fasteners, such as nuts and bolts, particularly in high torque applications. Reaction arm tools include a reaction arm fixed to a housing of the tool and engageable with a fixed structure (e.g., an adjacent fastener in a bolt pattern). When applying torque to a fastener, the reaction arm transmits the reaction torque to the fixed structure rather than to a user holding the tool.

### SUMMARY

Power tools, such as reaction arm tools, may include various operational modes or settings, which may be input or selected by an operator using a user interface assembly. In some embodiments, the present disclosure provides a reaction arm tool with a user interface that allows the operator to set a target torque to apply to a fastener. In some embodiments, the operator may also be able to receive information regarding operation of the tool via the user interface, such as an indication of whether the fastener has been tightened to the target torque. In some embodiments, the user interface assembly may also show telemetry data (e.g., motor torque, motor speed, motor temperature, and battery percentage) numerically or graphically.

In some aspects, the techniques described herein relate to a power tool including: a housing including a first clamshell portion and a second clamshell portion, the housing including a front end and a rear end; a motor positioned within the housing, the motor configured to rotate a motor shaft about a central axis; a gear case coupled to the housing and enclosing a drive train, the drive train configured to transmit torque from the motor shaft to an output drive extending from a front end of the gear case; a reaction arm coupled to the gear case, the reaction arm configured to engage a fixed feature to limit rotation of the gear case around the central axis; and an interface assembly including: an interface housing having a top portion positioned within the housing between the first clamshell portion and the second clamshell portion and a bottom portion extending outside the housing, the top portion including a lens opening, and the bottom portion including a plurality of actuator openings, an interface circuit board coupled to the interface housing, the interface circuit board including: a display panel positioned in line with the lens opening of the interface housing, and a plurality of switches positioned in line with the plurality of actuator openings in the interface housing, and a lens positioned within the lens opening.

In some aspects, the techniques described herein relate to 2. The power tool, wherein the interface assembly includes

In some aspects, the techniques described herein relate to an over-mold surrounding at least a portion of the interface housing, the over-mold including a plurality of actuators extending through the plurality of actuator openings, the actuators configured to be depressed to actuate a corresponding one of the plurality of switches.

In some aspects, the techniques described herein relate to a power tool, wherein the interface assembly includes a backing panel positioned between the display panel and the interface circuit board, and wherein the backing panel is formed of elastomeric material.

In some aspects, the techniques described herein relate to a power tool, wherein the interface assembly includes a gasket positioned between the lens and the display housing.

In some aspects, the techniques described herein relate to a power tool, wherein the display housing includes an alignment opening configured to receive an alignment protrusion formed on the first clamshell portion of the housing and another alignment protrusion formed on the second clamshell portion of the housing.

In some aspects, the techniques described herein relate to a power tool, wherein the display panel is configured to display an interface including a plurality of interface screens including a plurality of interface elements, and wherein the plurality of switches is configured to alter the interface screen shown on the display panel.

In some aspects, the techniques described herein relate to a power tool, wherein the plurality of switches includes: a set of navigation switches configured move between the plurality of interface elements on the interface screen currently being displayed, a return switch configured to change the interface screen to a previously shown interface screen, and a confirm switch configured to select one of the plurality of interface elements.

In some aspects, the techniques described herein relate to a power tool including: a housing including a first clamshell portion and a second clamshell portion, the housing including a front end and a rear end; a gear case extending from the front end of the housing; a motor positioned within the housing; an output drive extending from a front end of the gear case and configured to receive torque from the motor; and an interface assembly including: an interface housing having a top portion positioned within the housing between the first clamshell portion and the second clamshell portion and a bottom portion extending outside the housing, the top portion including an opening, an interface circuit board disposed within the interface housing, the interface circuit board including a display panel positioned in line with the opening of the interface housing.

In some aspects, the techniques described herein relate to a power tool, wherein the interface assembly includes an over-mold formed of an elastomeric material, wherein the over-mold surrounds the bottom portion of the interface housing.

In some aspects, the techniques described herein relate to a power tool, wherein the over-mold is a first over-mold, and wherein the first clamshell portion and the second clamshell portion each include a second over-mold, the second over-molds surrounding rear portions of the first and second clamshell portions.

In some aspects, the techniques described herein relate to a power tool, wherein the rear portions of the first and second clamshell portions surround the top portion of the interface housing.

In some aspects, the techniques described herein relate to a power tool, wherein the interface housing includes a plurality of actuator openings, wherein the over-mold includes a plurality of actuators extending through the plurality of actuator openings, the actuators configured to be depressed to actuate a corresponding one of a plurality of switches in line with the plurality of actuator openings in the interface housing.

In some aspects, the techniques described herein relate to a power tool, further including a reaction arm coupled to the gear case, the reaction arm configured to engage a fixed feature to limit rotation of the gear case.

In some aspects, the techniques described herein relate to a power tool, wherein the rear end of the housing includes opening in line with the opening of the interface housing.

In some aspects, the techniques described herein relate to a power tool including: a housing including a first clamshell portion and a second clamshell portion, the housing including a front end and a rear end; a gear case extending from the front end of the housing; a motor positioned within the housing; an output drive extending from a front end of the gear case and configured to receive torque from the motor; and an interface assembly including: an interface housing having a top portion positioned within the housing between the first clamshell portion and the second clamshell portion and a bottom portion, the top portion including a circular lens opening, an interface circuit board disposed within the interface housing, the interface circuit board including a display panel positioned in line with the lens opening of the interface housing, and a lens received within the lens opening.

In some aspects, the techniques described herein relate to a power tool, wherein the lens is offset from the rear end of the housing such that the lens is entirely disposed within the housing.

In some aspects, the techniques described herein relate to a power tool, wherein the bottom portion of the interface housing is positioned outside the housing.

In some aspects, the techniques described herein relate to a power tool, wherein the lens includes a lip extending along a perimeter of the lens to limit a distance the lens extends through the lens opening, wherein a gasket is positioned over the lip and between the lens and the display housing to seal the display housing from debris ingress.

In some aspects, the techniques described herein relate to a power tool, wherein the interface assembly includes an over-mold, wherein the over-mold surrounds the bottom portion of the interface housing.

In some aspects, the techniques described herein relate to a power tool, further including a reaction arm coupled to the gear case, the reaction arm configured to engage a fixed feature to limit rotation of the gear case.

### BRIEF DESCRIPTION OF THE DRAWINGS

FIG. 1 is a partially exploded perspective view of a power tool with a reaction arm according to an embodiment of the disclosure.

FIG. 2 is a section view of the power tool of FIG. 1.

FIG. 3 is a perspective view of a user interface assembly of the power tool of FIG. 1.

FIG. 4 is a section view of the user interface assembly of FIG. 3.

FIG. 5 is an exploded rear perspective view of the user interface assembly of FIG. 3.

FIG. 6 is an exploded front perspective view of the user interface assembly of FIG. 3.

FIG. 7 is a partial exploded rear perspective view of the power tool of FIG. 1, illustrating the user interface assembly of FIG. 3.

### DETAILED DESCRIPTION

Before any embodiments of the disclosure are explained in detail, it is to be understood that the disclosure is not limited in its application to the details of construction and the arrangement of components set forth in the following description or illustrated in the following drawings. The disclosure is capable of other embodiments and of being practiced or of being carried out in various ways.

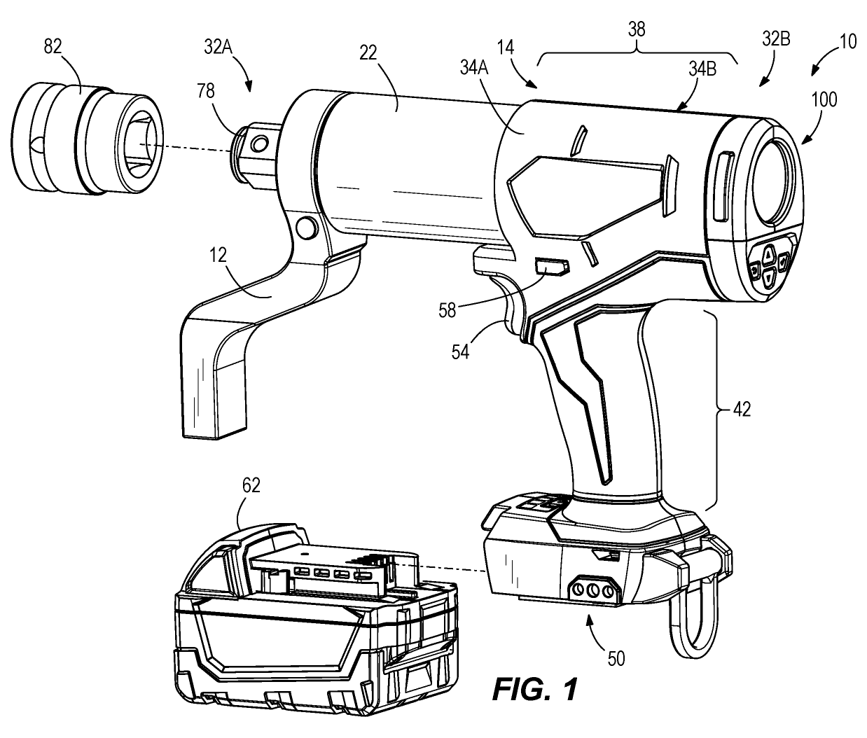

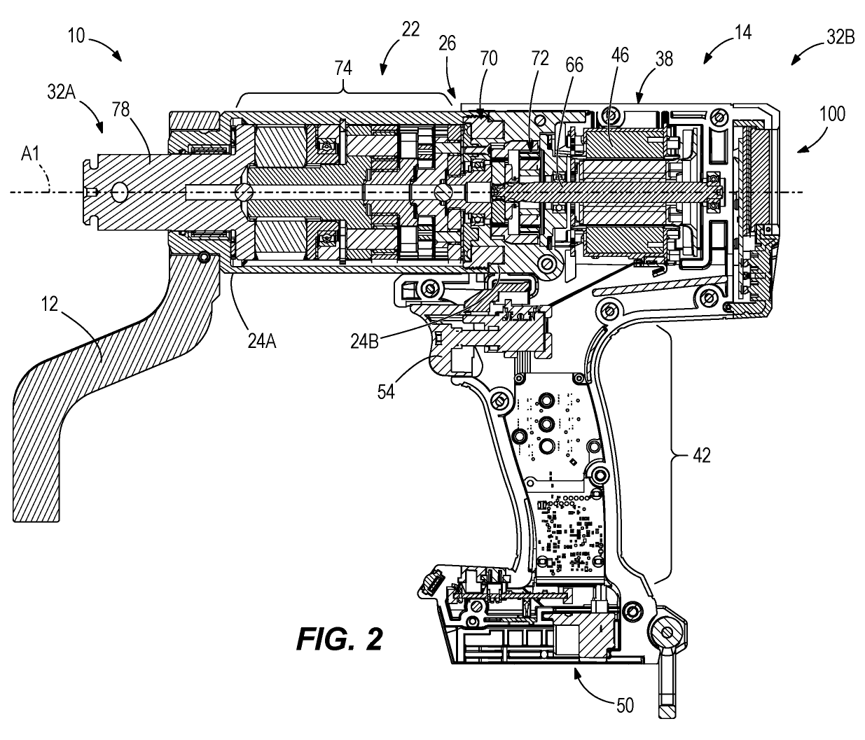

FIGS. 1-2 illustrate a power tool 10 configured to apply torque to a workpiece (e.g., a fastener). The illustrated power tool 10 is configured as a reaction arm tool and includes a reaction arm 12, a housing 14, a gear case 22, a drive train 26, and a user interface assembly 100. The power tool 10 defines a front end 32A facing the workpiece (not shown) during operation and a rear end 32B opposite to the front end 32A.

With continued reference to FIGS. 1-2, the reaction arm 12 is coupled to gear case 22 and is configured to rotate with respect to the housing 14 until the reaction arm 12 braces a fixed structure (e.g., an adjacent fastener, a wall, a clamp, etc.). When the reaction arm 12 braces against the fixed structure, the reaction torque generated by the drive train 26 is negated and an operator does not need to counteract the reaction torque. As such, the operator using the power tool 10 does not experience the reaction torque on their hands and wrists allowing for higher torque outputs, repeatability, and reduced operator fatigue.

With continued reference to FIGS. 1-2, the housing 14 is formed of a first clamshell portion 34A and a second clamshell portion 34B, and both the first and second clamshell portions 34A, 34B are coupled together using a plurality of fasteners (not shown). The housing 14 is also split into a motor housing portion 38 and a handle portion 42. The motor housing portion 38 is configured to receive a motor 46, a portion of the gear case 22, and a portion of the user interface assembly 100. The motor 46, which in the illustrated embodiment is a brushless, direct-current motor, is configured to rotate a motor shaft 66 around a central axis A1.

The handle portion 42 is configured to be gripped by the operator to position the power tool 10. In the illustrated embodiment, the handle portion 42 is a D-shaped grip. In other embodiments, the handle portion 42 may be a pistol grip. The handle portion 42 includes a battery receptacle 50, a trigger 54, and a forward/reverse switch 58. The battery receptacle 50 is configured to couple a battery pack 62 mechanically and electrically to the power tool 10. The trigger 54 and the forward/reverse switch 58 are both configured to set an operating speed and a direction of rotation of the motor 46.

With continued reference to FIGS. 1-2, the gear case 22 is partially positioned within and extends beyond the housing 14. In other embodiments, the gear case 22 may be coupled only to the exterior of the housing 14 or may be completely housed within the housing 14. The illustrated gear case 22 includes a front gear case 24A and a rear gear case 24B. The front gear case 24A extends beyond the housing 14 and includes a plurality of outer teeth (not shown) configured to receive and transmit torque to the reaction arm 12. The rear gear case 24B is positioned within housing 14 and is coupled to the front gear case 24A via a clutch assembly 70.

With continued reference to FIGS. 1-2, the drive train 26 is positioned within the gear case 22 and is configured to receive torque from the motor shaft 66 of the motor 46. The drive train 26 includes a first planetary transmission assembly 72, a second planetary transmission assembly 74, and an output drive 78. The first planetary transmission assembly 72 includes a plurality of planetary gear stages (e.g., two gear stages), with a first stage meshed within a pinion fixed to, or, in some embodiments, integrally formed with, the motor shaft 66. An output of the last stage of the first planetary transmission assembly 72 provides a torque input (e.g., as a sun gear) to a first planetary gear stage of a plurality of planetary gear stages (e.g., four gear stages) of the second planetary transmission assembly 74. In the illustrated embodiment, the interior of the front gear case 24A includes gear teeth such that the front gear case 24A defines a common ring gear for each of the plurality of gear stages of the second planetary transmission assembly 74.

The output drive 78 defines a last stage carrier of the second planetary transmission assembly 74 and extends from the front gear case 24A such that the output drive 78 is configured to receive a tool bit 82 (FIG. 1). The tool bit 82 engages a fastener and applies torque generated by the motor 46 and the drive train 26 to tighten or loosen the fastener. In the illustrated embodiment, the output drive 78 includes a square drive (e.g., a 1-inch square drive, a 3/4-inch square drive, or the like). In other embodiments, the output drive 78 may be a splined shaft, a hex shaft, a D shaft, a double D shaft, or the like. In yet other embodiments, the output drive 78 may include a chuck or bit holder.

With reference to FIG. 2, the front gear case 24A is fixed against rotation relative to the rear gear case 24B by the clutch assembly 70. The clutch assembly 70 may include, for example, clutch balls, pins, or the like, biased into engagement with one or more ramped cam surfaces, friction discs, or any other suitable arrangement that permits torque transmission through the clutch assembly 70 up to a threshold slip torque of the clutch assembly 70. Once the threshold slip torque is reached, the clutch assembly 70 slips and permits the front gear case 24A to rotate relative to the rear gear case 24B. Because the front gear case 24A is also the ring gear of the second planetary transmission assembly 74, rotation of the front gear case 24A effectively disables torque transmission to the output drive 78. That is, torque in excess of the threshold slip torque causes the front gear case 24A to rotate instead of rotating the output drive 78. In this way, the tool 10 can be mechanically prevented from outputting a torque above a predetermined torque limit (i.e. the threshold slip torque of the clutch assembly 70) if the user fails to engage the reaction arm 12 against a fixed support during use. When the reaction arm 12 is engaged against a fixed support, the reaction arm 12 receives the reaction torque and rotationally fixes the front gear case 24A.

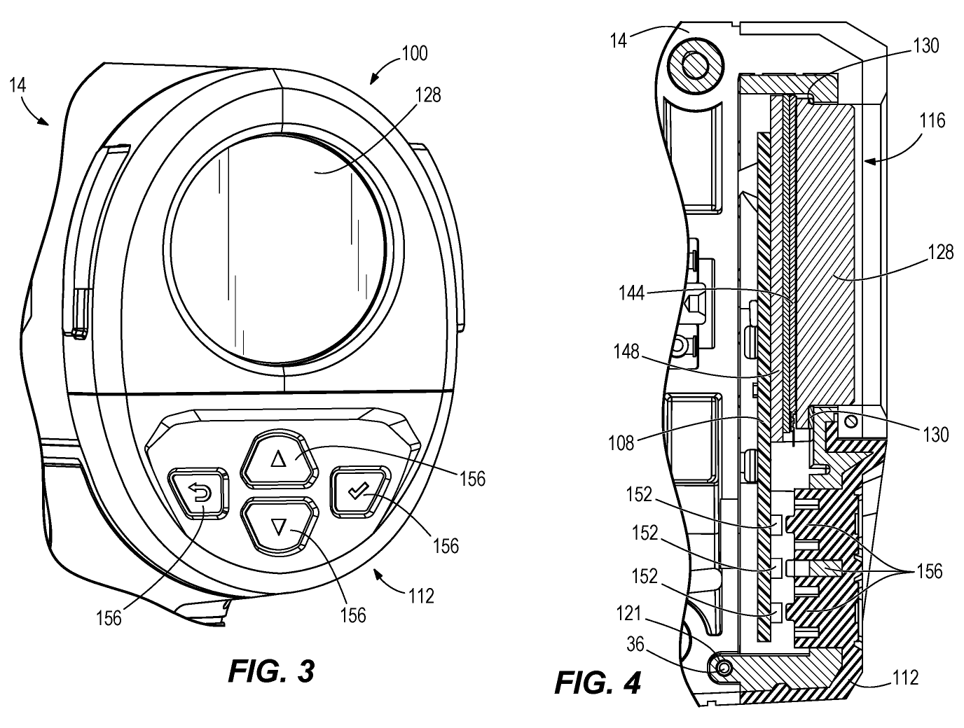

FIGS. 3-6 illustrates the user input assembly 100 positioned at the rear end 32B of the housing 14. More specifically, the user interface assembly 100 is positioned between the first clamshell portion 34A and the second clamshell portion 34B of the housing 14 and includes portions visible from an exterior of the power tool 10. In other embodiments, the user interface assembly 100 is coupled to an exterior the housing 14 using fasteners or may be positioned on a right side, a left side, a top side, or a bottom side of the housing 14. The user interface assembly 100 is configured to display operational characteristics, alter operational parameters, and toggle between different operating modes of the power tool 10. The user interface assembly 100 includes a display housing 104, a user interface circuit board 108, and an over-mold 112.

With reference to FIGS. 3-7, the display housing 104 is configured to receive the user interface circuit board 108. The display housing 104 includes a top portion 106A and a bottom portion 106B. The top portion 106A includes a lens opening 116. In the illustrated embodiment, the lens opening 116 is a circular opening configured to receive a lens 128. In other embodiments, the lens opening 116 may be square, rectangular, hexagonal, octagonal, or polygonal. In the illustrated, embodiment the lens 128 is formed as an ellipsoid. In other embodiments, the lens 128 may be formed as a circle, a square, or any other desired shape. The top portion 106A of the display housing 14 is positioned between the first clamshell portion 34A and the second clamshell portion 34B. In the illustrated embodiment, the bottom portion 106B of the display housing 104 extends downwardly from and is not captured between the clamshell portions 34A, 34B. However, in other embodiments, the clamshell portions 34A, 34B may also extend along the sides of the bottom portion 106B.

The bottom portion 106B of the display housing 104 includes a plurality of actuator openings 120 and an alignment opening 121. The plurality of actuator openings 120 are arranged in a “+” configuration and are configured to receive a plurality of actuators 156. The alignment opening 121 is located on the sagittal plane of the display housing 104 and is configured to receive a set of alignment protrusions 36 formed on the first clamshell portion 34A and the second clamshell portion 34B. When the set of alignment protrusions 36 are received in the alignment opening 121, the display housing’s 104 motion within the housing 14 is limited. In other embodiments, the lens opening 116, the plurality of actuator openings 120, and the alignment opening 121 may be located on different portions of the display housing 104.

With continued reference to FIGS. 3-6, the user interface circuit board 108 is coupled to the display housing 104. In the illustrated embodiment, the user interface circuit board 108 is coupled to the display housing 104 using a plurality of fasteners (not shown) received in a plurality of threaded openings 140. The user interface circuit board 108 includes a display panel 144, a backing panel 148, and a plurality of switches 152.

The display panel 144 is positioned between the user interface circuit board 108 and the lens 128. In the illustrated embodiment, the display panel 144 is an LCD display configured to display a graphical user interface (GUI) to the operator. In other embodiments, the display panel 144 may be an OLED panel or a E-Ink panel. The GUI includes a plurality of user interface elements (e.g., buttons, text fields, images, toggles, drop downs, progress bars) arranged on a user interface screens. In an exemplary embodiment, the user interface shown on the display panel 144 may include a display element representing one or more of the following: a motor speed, a motor temperature, a radial displacement of the output drive 78, a battery voltage, a battery capacity percentage, a real-time output torque, a real-time output speed, and/or a target torque. The display element may be text, numbers, or a graphical element.

The lens 128 is configured to protect the display panel 144 from scratching or cracking. The lens 128 is shaped to fit within the lens opening 116 of the display housing 104. Additionally, the lens 128 includes a lip 132 extending along the perimeter of the lens 128 to limit the distance the lens 128 extends through the lens opening 116. In the illustrated embodiment, a gasket 130 is positioned over the lip 132 and between the lens 128 and the display housing 104 to seal the display housing 104 from debris ingress. The lens 128 is composed of a clear material, such as acrylic, polycarbonate, glass, or sapphire.

The backing panel 148 is positioned between the display panel 144 and the user interface circuit board 108. The backing panel 148 is configured to protect the display panel 144 from damage by dampening excess vibrations from the operation of the power tool 10, from drops, or from impacts. In the illustrated embodiment, the backing panel 148 is composed of foam. In other embodiments, the backing panel 148 may be composed of an elastomeric nonconductive material.

The plurality of switches 152 are positioned on the user interface circuit board 108 adjacent to the display panel 144 and are aligned with the plurality of actuator openings 120. In the illustrated embodiment, the plurality of switches 152 include 4 switches 152, which are positioned below the display panel 144. Also, in the illustrated embodiment, the 4 switches 152 are arranged in a “+” pattern. In other embodiments, the user interface circuit board 108 may include more or less than 4 switches 152. In further embodiments, plurality of switches 152 may be positioned along a straight line, in a square configuration, or in a circular configuration.

The plurality of switches 152 are configured to navigate the GUI shown on the display panel 144. In the illustrated embodiment, the plurality of switches 152 includes a set of navigation switches 152A, a confirm switch 152B, and a return switch 152C. The set of navigation switches 152A are configured to move from a first user interface element to a second user interface element or set a parameter value. The confirm switch 152B is configured to select a particular user interface element or change from a currently shown user interface screen to a new user interface screen. The return switch 152C is configured to return from the new user interface screen to the previously shown user interface screen. Using a combination of the switches 152A-152C, the user can change which operational characteristics are displayed, alter operational parameters, and toggle between different operating modes. In other embodiments, the plurality of switches 152 may be replaced with or included in combination with one or more of the following: a scroll wheel, a track ball, or a capacitive touch surface.

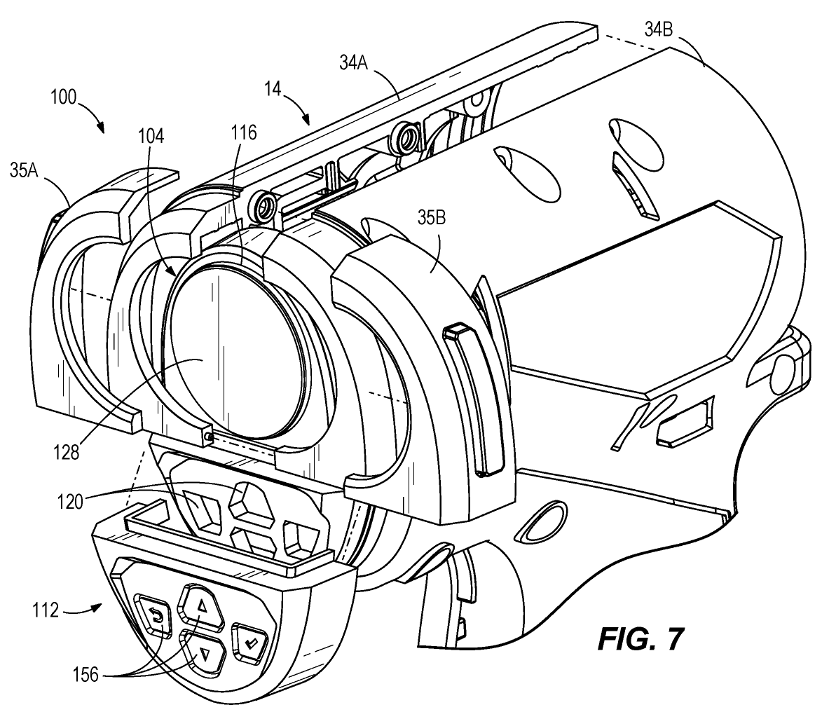

With continued references to FIGS. 3-6, the over-mold 112 surrounds the bottom portion 106B of the display housing 104 and is at least partially positioned between the housing 14 and the display housing 104. In the illustrated embodiment, a portion of the over-mold 112 surrounding the bottom portion 106B is exposed to the exterior of the power tool 10. In other embodiments, different portions of the over-mold 112 may be surrounded by the housing 14 or exposed to the exterior of the power tool 10. The over-mold 112 is composed of a deformable elastomeric material and is configured to absorb excess vibrations generated during operation of the power tool 10, from drops, or from impacts. In some embodiments, as shown in FIG. 7, the clamshell housing portions 34A, 34B may additionally include respective overmolds 35A, 35B surrounding rear portions of the clamshell housing portions 34A, 34B that in turn surround the upper portion 106A of the display housing 104. These overmolds 35A, 35B are also preferably made of an elastomeric material to protect the display housing 104 from drops or impacts.

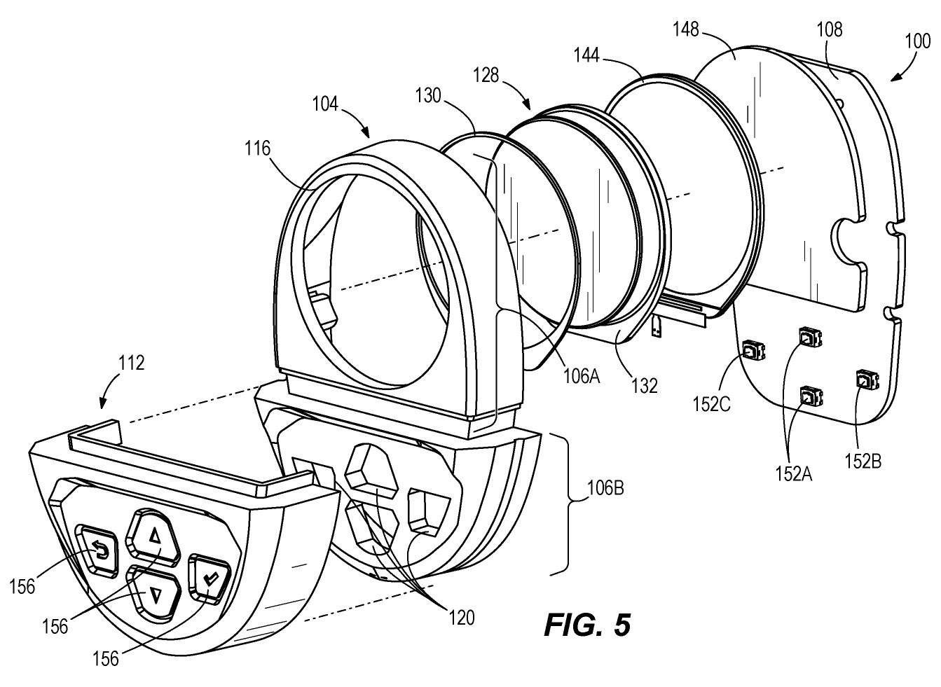

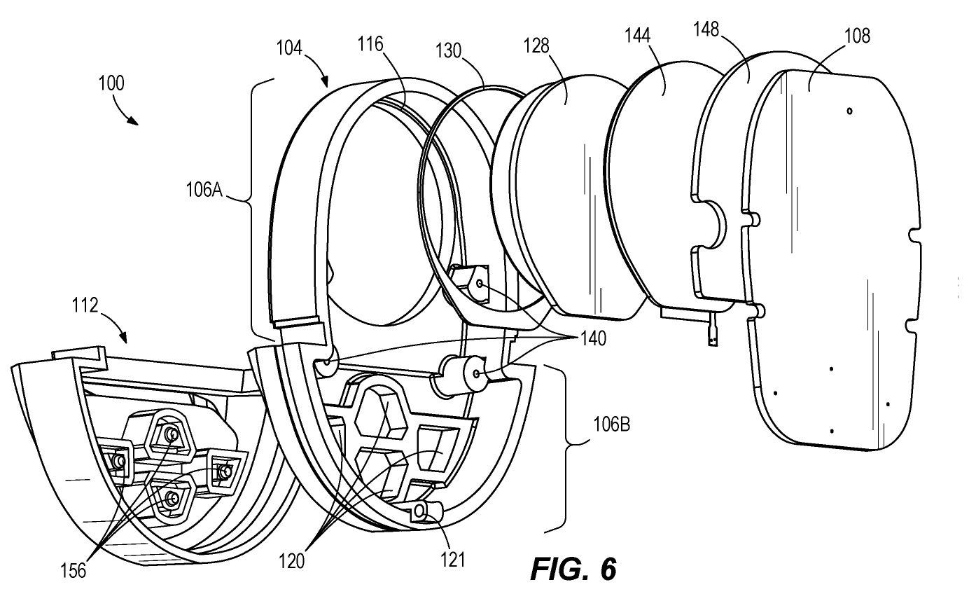

Returning to FIGS. 5-6, the over-mold 112 includes a plurality of actuators 156 positioned in the plurality of actuator openings 120 of the display housing 104. Each of the actuators 156 corresponds to one of the switches 152A-C and is configured to depress and activate the corresponding switch 152A-C. In use, the operator applies an axial force to one or more of the actuators 156 and the actuator 156 deforms towards the corresponding switch 152. When the actuator 156 contacts the switch 152, a signal is sent to alter the GUI shown on the display panel 144. Additionally, each of the actuators 156 includes a debossed icon, formed on an outward facing surface, representing the function of the corresponding switch 152A-C. In other embodiments, the icon may be embossed, may be printed, or may be a sticker applied to the outward facing surface.

To assemble the user interface assembly 100, the over-mold 112 is injection molded over an exterior surface of the display housing 104. During the injection molding procedure, the plurality of actuators 156 are formed and extend into the plurality of actuator openings 120. Next, the gasket 130 is first positioned around the lens 128, and then the lens 128 is inserted into the lens opening 116 of the display housing 104. Then, the user interface circuit board 108 is coupled to the display housing 104 via a plurality of fasteners installed in the plurality of threaded openings 140.

Now, the user interface assembly 100 is assembled and may be inserted into the housing 14 of the power tool 10. To insert the user interface assembly 100 into the housing 14, the set of alignment protrusions 36 of the first clamshell portion 34A or the second clamshell portion 34B must be aligned and inserted into the alignment opening 121 of the display housing 104. Then, the remaining alignment protrusion 36 of the remaining clamshell portion is also inserted into the alignment opening 121. Finally, a plurality of fasteners may be installed to couple the first clamshell portion 34A and the second clamshell portion 34B to seal the housing 14.

Although the disclosure has been described in detail with reference to certain preferred embodiments, variations and modifications exist within the scope and spirit of one or more independent aspects of the disclosure as described.

Various features of the disclosure are set forth in the following claims.

What is claimed is:

1. A power tool comprising:
a housing comprising a first clamshell portion and a second clamshell portion, the housing including a front end and a rear end;
a motor positioned within the housing, the motor configured to rotate a motor shaft about a central axis;
a gear case coupled to the housing and enclosing a drive train, the drive train configured to transmit torque from the motor shaft to an output drive extending from a front end of the gear case;
a reaction arm coupled to the gear case, the reaction arm configured to engage a fixed feature to limit rotation of the gear case around the central axis; and
an interface assembly including:
an interface housing having a top portion positioned within the housing between the first clamshell portion and the second clamshell portion and a bottom portion extending outside the housing, the top portion including a lens opening, and the bottom portion including a plurality of actuator openings,
an interface circuit board coupled to the interface housing, the interface circuit board including:
a display panel positioned in line with the lens opening of the interface housing, and
a plurality of switches positioned in line with the plurality of actuator openings in the interface housing, and
a lens positioned within the lens opening.

2. The power tool of claim 1, wherein the interface assembly includes an over-mold surrounding at least a portion of the interface housing, the over-mold including a plurality of actuators extending through the plurality of actuator openings, the actuators configured to be depressed to actuate a corresponding one of the plurality of switches.

3. The power tool of claim 1, wherein the interface assembly includes a backing panel positioned between the display panel and the interface circuit board, and wherein the backing panel is formed of elastomeric material.

4. The power tool of claim 1, wherein the interface assembly includes a gasket positioned between the lens and the display housing.

5. The power tool of claim 1, wherein the display housing includes an alignment opening configured to receive an alignment protrusion formed on the first clamshell portion of the housing and another alignment protrusion formed on the second clamshell portion of the housing.

6. The power tool of claim 1, wherein the display panel is configured to display an interface comprising a plurality of interface screens including a plurality of interface elements, and wherein the plurality of switches is configured to alter the interface screen shown on the display panel.

7. The power tool of claim 6, wherein the plurality of switches includes:
a set of navigation switches configured move between the plurality of interface elements on the interface screen currently being displayed,
a return switch configured to change the interface screen to a previously shown interface screen, and
a confirm switch configured to select one of the plurality of interface elements.

8. A power tool comprising:
a housing comprising a first clamshell portion and a second clamshell portion, the housing including a front end and a rear end;
a gear case extending from the front end of the housing;
a motor positioned within the housing;
an output drive extending from a front end of the gear case and configured to receive torque from the motor; and
an interface assembly including:
an interface housing having a top portion positioned within the housing between the first clamshell portion and the second clamshell portion and a bottom portion extending outside the housing, the top portion including an opening,
an interface circuit board disposed within the interface housing, the interface circuit board including a display panel positioned in line with the opening of the interface housing.

9. The power tool of claim 8, wherein the interface assembly includes an over-mold formed of an elastomeric material, wherein the over-mold surrounds the bottom portion of the interface housing.

10. The power tool of claim 9, wherein the over-mold is a first over-mold, and wherein the first clamshell portion and the second clamshell portion each include a second over-mold, the second over-molds surrounding rear portions of the first and second clamshell portions.

11. The power tool of claim 10, wherein the rear portions of the first and second clamshell portions surround the top portion of the interface housing.

12. The power tool of claim 9, wherein the interface housing includes a plurality of actuator openings, wherein the over-mold includes a plurality of actuators extending through the plurality of actuator openings, the actuators configured to be depressed to actuate a corresponding one of a plurality of switches in line with the plurality of actuator openings in the interface housing.

13. The power tool of claim 8, further comprising a reaction arm coupled to the gear case, the reaction arm configured to engage a fixed feature to limit rotation of the gear case.

14. The power tool of claim 8, wherein the rear end of the housing includes opening in line with the opening of the interface housing.

15. A power tool comprising:
a housing comprising a first clamshell portion and a second clamshell portion, the housing including a front end and a rear end;
a gear case extending from the front end of the housing;
a motor positioned within the housing;
an output drive extending from a front end of the gear case and configured to receive torque from the motor; and
an interface assembly including:
an interface housing having a top portion positioned within the housing between the first clamshell portion and the second clamshell portion and a bottom portion, the top portion including a circular lens opening,
an interface circuit board disposed within the interface housing, the interface circuit board including a display panel positioned in line with the lens opening of the interface housing, and
a lens received within the lens opening.

16. The power tool of claim 15, wherein the lens is offset from the rear end of the housing such that the lens is entirely disposed within the housing.

17. The power tool of claim 15, wherein the bottom portion of the interface housing is positioned outside the housing.

18. The power tool of claim 15, wherein the lens includes a lip extending along a perimeter of the lens to limit a distance the lens extends through the lens opening, wherein a gasket is positioned over the lip and between the lens and the display housing to seal the display housing from debris ingress.

19. The power tool of claim 15, wherein the interface assembly includes an over-mold, wherein the over-mold surrounds the bottom portion of the interface housing.

20. The power tool of claim 15, further comprising a reaction arm coupled to the gear case, the reaction arm configured to engage a fixed feature to limit rotation of the gear case.
